(19) United States
(12) Patent Application Publication
(10) Pub. No.: US 2009/0088990 A1
(43) Pub. Date: Apr. 2, 2009

(54) SYNCHRONIZED PHASOR PROCESSOR FOR A POWER SYSTEM

(76) Inventors: Edmund O. Schweitzer, III, Pullman, WA (US); David E. Whitehead, Pullman, WA (US); Armando Guzman-Casillas, Pullman, WA (US); Charles E. Petras, Pullman, WA (US)

Correspondence Address: Schweitzer Engineering Laboratories, Inc.;Richard Edge, 2350 NE HOPKINS COURT, PULLMAN, WA, 99163-5603, US

(21) Appl. No.: 12/239,684

(22) Filed: Sep. 26, 2008

Related U.S. Application Data
(60) Provisional application No. 60/976,440, filed on Sep. 30, 2007.

(51) Int. Cl. G01R 31/00

(52) U.S. Cl. 702/58

(57) ABSTRACT

A device is provided for monitoring and controlling various power system device and elements. The device generally includes a communications channel for receiving phasor data associated with a location on the power system. The device further includes a logic engine which performs scalar, vector and/or other complex calculation based on the phasor data to provide control data or an output signal for effecting the various other power system devices or elements to provide local or wide area protection, control, and monitoring to maintain power system stability.

### CROSS-REFERENCE TO RELATED APPLICATION

This application claims benefit under 35 U.S.C. §119(e) of US Provisional Application Ser. No. 60/976,440, entitled “SYNCHRONIZED PHASOR VECTOR PROCESSOR FOR A POWER SYSTEM,” filed Sep. 30, 2007, naming Edmund O. Schweitzer, III, David E. Whitehead, Armando Guzman-Casillas and Charles E. Petras as inventors, the complete disclosure thereof being incorporated herein by reference.

### FIELD OF THE INVENTION

The present invention relates generally to a device and system for providing control data and signals to other devices within a power system. More specifically, a device and system is provided which receives and processes synchronized phasor measurements in real-time to provide control data and signals to other devices within a power system.

### BACKGROUND OF THE INVENTION

Wide-Area Measurement Systems (WAMSs) are used to monitor power system disturbances. WAMSs generally include among other things phasor measurement units (PMUs), phasor data concentrators (PDCs), visualization software and data archiver software. PMUs are placed at various locations within the power system to acquire voltage and current phasor measurements therefrom. These PMUs may be adapted to time-stamp such data. PDCs may be adapted to collect the phasor measurements from the PMUs and time-align such data. Using visualization and data archiver software, the power system may be monitored using phasor measurements acquired by the PMUs. In this way, WAMSs generally provide real-time information relating to transmission line power flows, bus voltage magnitude and angle, and frequency measurements across the transmission network. WAMSs also provide information for post-mortem analysis (e.g., power system modal analysis and power system validation).

Various devices in the WAMS have also been used to control devices within the power system. For example, FIG. 1 illustrates a prior art system which uses time-correlated data to monitor and control power systems. The system of FIG. 1 generally comprises a plurality of PMUs 100a, b, c; a PDC 102; a control unit 104 (which may be a wide-area control system (WACS)) and a command unit 106 (which may be a wide-area protection system (WAPS) controller). The PMUs 100 are placed at various locations of the power system to acquire voltage and current phasor measurements therefrom. These PMUs may be adapted to time-stamp such data. The PDC 102 is adapted to collect the phasor measurements from the PMUs and time-align such data. A control unit 104 is provided to generally process the time-aligned data and determine whether the command unit 106 should send a subsequent command to appropriate power system devices or power system elements for protection functionality (e.g., shed generation, insert a system braking resistor or control a Static VAR Compensator). Nevertheless, the complex system illustrated in FIG. 1 consists of a disjointed and fragmented collection of devices that make the system unreliable and difficult to implement.

In another prior art system as shown in FIG. 2, protective relays have been used to monitor and control the power system in what is commonly referred to as a Remedial Action Scheme (RAS) system. Protective relays (e.g., at 200) are placed at various locations of the power system to acquire power system data (e.g., current and voltage measurements) therefrom. During an abnormal condition, the protective relay 200 asserts a contact that is monitored by a plurality of I/O modules 204a, b, c which transmit the status to a respective logic processor 206 a, b, c. Each logic processor 206a, b, c processes the power system data to determine whether to make a control decision and shares such determination with the other logic processors 206a, b, c. Each logic processor 206a, b, c, in turn, compares the shared determination with its own determination. If the determination to make a control decision to effect the power system is shared by the logic processors 206a, b, c, a control decision is issued through a plurality of I/O modules 208a, b, c, to a protective relay 210 to effect a device 212 in the power system (e.g., generator relay 210 trip a breaker 212). FIG. 2 further shows a timing diagram for the above described events in the traditional RAS system. Nevertheless, it is desirable to provide a device which eliminates the use of post-processed trip outputs to effect various power system devices, thereby reducing the speed inefficiencies inherent therein.

Several desired benefits of the preferred embodiments, including combinations of features thereof, of the invention will become apparent from the following description. It will be understood, however, that an arrangement could still appropriate the claimed invention without accomplishing each and every one of these desired benefits, including those gleaned from the following description. The appended claims, not these desired benefits, define the subject matter of the invention. Any and all benefits are derived from the multiple embodiments of the invention, not necessarily the invention in general.

### SUMMARY OF THE INVENTION

Provided is a device which processes phasor data, real values, and Boolean values in a time deterministic fashion. Generally, the device is adapted to receive phasor data, time-align such data, process such data (e.g., using vector calculations), execute programmable logic using the processed data, and send control data or an output signal to other power system devices in real-time.

The device generally includes a communications channel for receiving phasor data associated with a location on the power system and a processor including a logic engine to perform scalar, vector and/or other complex calculations based on the phasor data. For example, the received phasor data may include phasor measurement data, synchronized phasor measurement data or synchrophasor data, and a processor is adapted to perform complex calculations using such measurements. Based on the calculated data, the processor provides control data or an output signal for effecting the various other power system devices or elements to provide local or wide area protection, control, and monitoring to maintain power system stability. In one embodiment, the processor is configurable to define various scalar, vector and/or other complex calculations to be processed thereby.

In another embodiment, the phasor data is received by the device in various messaging formats. The device includes a protocol conversion module for translating the various received messages into a common data format.

In yet another embodiment, the device further includes a protocol generator coupled to the logic engine for converting the control data or output signal to an appropriate messaging format or protocol understandable by other power system devices or elements.

In yet another embodiment, the device further comprises a run-time system having a plurality of configurable power system control modules. Each control module defines a set of scalar, vector and/or other complex calculations for determining control data or an output signal for effecting at least one of the various other power system devices or elements to provide local or wide area protection, control, and monitoring to maintain power system stability.

In yet another aspect, provided is a system for monitoring and protecting an area of a power system. The system generally comprises a plurality of phasor measurement units for acquiring phasor data from the area of the power system. A control device is provided having a communications channel for receiving the phasor data and a processor including a logic engine for performing scalar, vector and/or other complex calculations based on the phasor data to provide control data or an output signal. A plurality of other power system devices or elements are adapted to receive the control data or output signals and in response thereto provide protection, control, and monitoring to maintain power system stability to the area of the power system.

### BRIEF DESCRIPTION OF THE DRAWINGS

FIG. 1 is a general block diagram of prior art system which uses time-correlated data to monitor and control power systems.

FIG. 2 is a general block diagram of a prior art system which uses protective relays to monitor and control power systems in what is commonly referred to as a Remedial Action Scheme (RAS) system.

FIG. 3 is a general block diagram of a system for monitoring and controlling an area of a power system by processing power system data including phasor data and transmitting control data or signals based on such processing to other power system devices in real-time.

FIG. 4 is a block diagram of a processor for use in a device for monitoring and controlling an area of a power system by processing power system data including phasor data and transmitting control data or signals based on such processing to other power system devices in real-time.

FIG. 5 is a circuit block diagram of a processor for use in a device for monitoring and controlling an area of a power system by processing power system data including phasor data and transmitting control data or signals based on such processing to other power system devices in real-time.

FIG. 6 is a general block diagram illustrating the inputs and outputs of the processors of FIGS. 4 and 5.

FIG. 7 is a circuit block diagram of a processor including a run-time system for use in a device for monitoring and controlling an area of a power system by processing power system data including phasor data and transmitting control data or signals based on such processing to other power system devices in real-time.

FIG. 8 is a general block diagram showing an application of a system for monitoring and controlling an area of a power system by processing power system data including phasor data and transmitting control data or signals based on such processing to other power system devices in real-time.

FIG. 9 is a general block diagram showing an application of a system for monitoring and controlling an area of a power system by processing power system data including phasor data and transmitting control data or signals based on such processing to other power system devices in real-time.

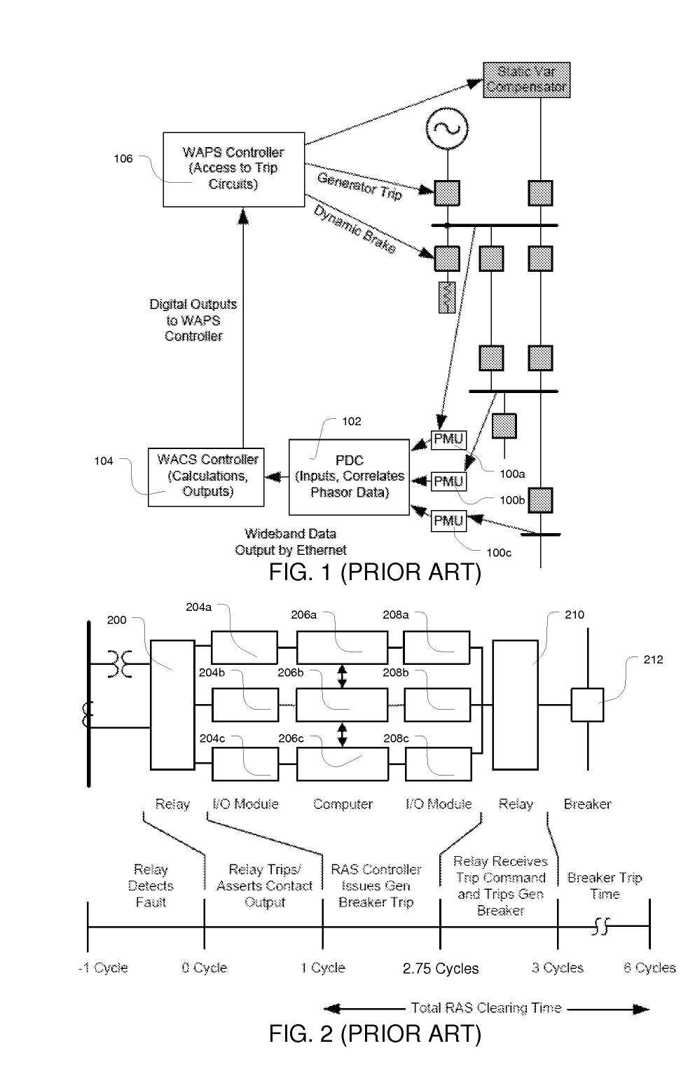

### DESCRIPTION OF THE VARIOUS EMBODIMENTS

Provided is a system and device which processes phasor data, real values, and Boolean values in a time deterministic fashion to reduce complexity and improve power system reliability. Generally, the device is adapted to receive phasor data, time-align such data, process such data (e.g., using vector calculations), execute programmable logic using the processed data, and send control data or signals to other power system devices in real-time.

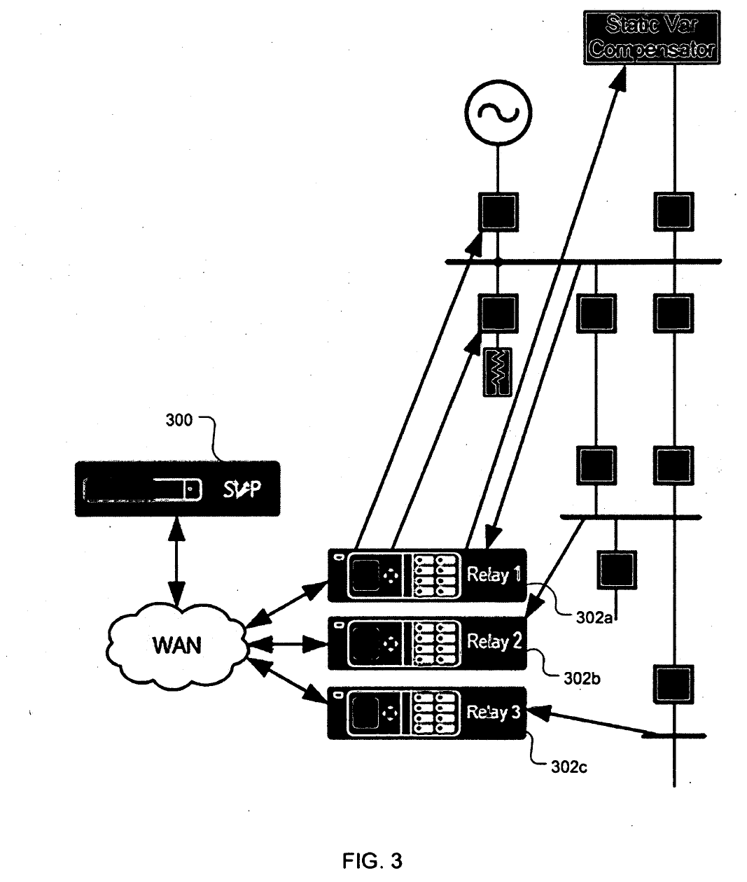

For example, as shown in FIG. 3, a device 300 is generally adapted to receive phasor data from various locations in the power system via a plurality of PMCUs 302a, b, c. For example, the received phasor data may include phasor measurement data, synchronized phasor measurement data or synchrophasor data. Device 300 may be in the form of an intelligent electronic device (IED), synchrophasor processor, phasor data concentrator (PDC), phasor measurement unit (PMU), protective relay, a computing device, or any similar power system device. The device 300 may be adapted to time-align this phasor data or, alternatively, another associated device (not shown) may be provided to time-align this phasor data. The device 300 generally includes a processor for performing, among other things, vector and scalar calculations on the phasor data along with real values and Boolean values in a time deterministic fashion, generally about real-time. Using this processed data, the device 300 provides output data and/or signals in order to initiate various control and/or monitoring functions to control other power system devices or power system elements.

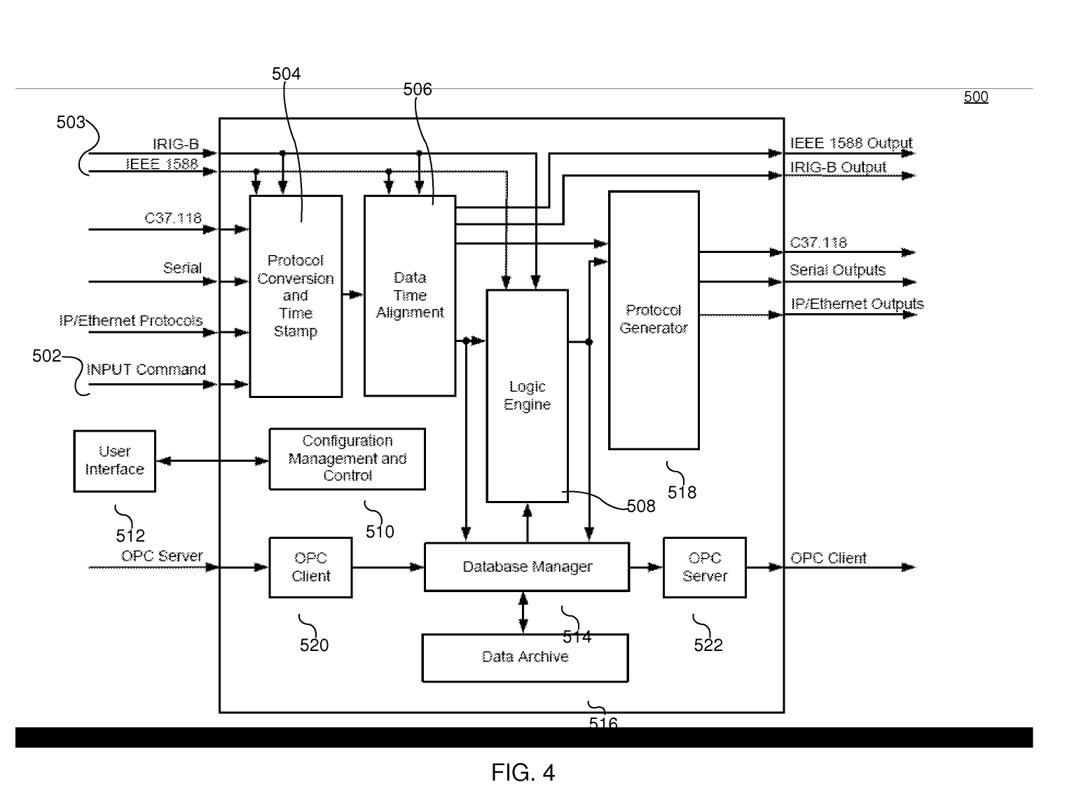

FIG. 4 illustrates an example of the internal architecture of the processor 500. More specifically, the processor 500 may generally include a plurality of communications channels 502 for receiving power system data including phasor data from a plurality of power system devices or elements associated with an area of the power system. For example, the received power system data may include phasor data having phasor measurement data, synchronized phasor measurement data or synchrophasor data. In one example, each of the power system devices may be communicatively coupled to a current and/or voltage sensor, which may be configured to obtain current and/or voltage measurements. The current and/or phase measurements obtained by sensors may comprise measurements of one or more phases of a three-phase current and/or voltage signal.

The time signal may be from a common time source. The common time source may be any time source available to several devices on the WAN. The common time source may include an absolute time source. Some examples of common time sources that may be used include: a clock internal to one of the devices on the WAN; a single clock on the WAN; a WWB time signal; a WWVB time signal; an IRIG-B signal from e.g. a global positioning system satellite system; and the like.

The power system data may be transferred via a number of communications messaging or protocols format/structures, including but not limited to IEEE C37.118 messages, serial communications, IP/Ethernet protocols (e.g., SCADA, and/or protection messages), input commands and the like. In this arrangement, the processor 500 is further adapted to receive time information from external time sources 503 such as IRIG and IEEE 1588 and output such time information to both internal and external time clients. A configuration management and control (CMC) module 510 which is coupled to a user interface 512 is further provided to allow a user to define and control the various communications inputs.

A protocol conversion and timestamp module 504 is provided to translate the received messages or protocol into a common data format/structure. The protocol conversion and timestamp module 504 is adapted to timestamp any data which is communicated via a messaging format or protocol which does not support time information. Time information from external time sources such as IRIG and IEEE 1588 are generally used to timestamp the received data. The timestamp may be generated in any form known in the art, including a Universal Coordinated Timestamp (UTC), Unix timestamp, an offset time, or the like. Examples of such messaging formats or protocols which do not support time information include Modbus and SEL Fast Message protocols. Examples of such messaging formats or protocols which include time information in the form of a timestamp or otherwise include the IEEE C37.118, IEC 61850 and SEL Synchrophasor Fast Message protocols. It is to note that the protocol conversion and timestamp module 504 may be separate and apart from the processor 500 without deviating from the spirit of the invention.

Power system data may be measured accurately. Nevertheless, such data may be transferred to the processor 500 via the communications links 502 at different times due to unequal communication delays for each type of transferred data. Accordingly, the translated data from the protocol conversion and timestamp module 504 is communicated to a data time alignment module 506. The data time alignment module 506 correlates the translated data to compensate for any unequal communication delays.

The aligned power system data is then communicated to a logic engine 508. The logic engine 508 may be generally in the form of a programmable logic controller (PLC) or any other suitable processing unit which performs scalar, vector or other complex calculations based on the aligned power system data to provide control data or an output signal for effecting other power system devices or elements to provide local or wide area protection, control, and monitoring to maintain power system stability. Time information from the external time sources are generally used by the logic engine 508 as an accurate clock source. The logic engine 508 may also be associated with a configuration management and control (CMC) module 510 which is coupled to a user interface 512. This arrangement provides a user the ability to define various algorithms to be processed by the logic engine 508. In one embodiment, the logic engine 508 may be adapted use the IEC 61131-3 programming language, which is generally the standard programming language used in industrial control, SCADA system, DCS, and other power system applications.

The logic engine 508 may further be coupled to a database manager 514 and data archive 516. The database manager 514 formats aligned data from the data time alignment module 506 and control data from the logic engine 508 and stores such in the data archive 516. The logic engine 508 may be adapted to retrieve any such stored or archived data for use in its calculations. A configuration management and control (CMC) module 510 which is coupled to a user interface 512 is further provided to allow a user to provide for database management.

The logic engine 508 is coupled to a protocol generator 518 such that the control data is converted to an appropriate messaging format or protocol understandable by other power system devices or elements. These messaging formats or protocols may include, but are not limited to, IEEE C37.118, DNP3 LAN/WAN, Modbus RTU, SEL Mirrored Bits communications, SEL Fast Messaging, etc. After the data conversion, the processor 500 is adapted to communicate understandable control data or output signals for effecting other power system devices or elements to provide local or wide area protection, control, and monitoring to maintain power system stability. Time information from the external time sources may optionally be used by the protocol generator to timestamp the control data or output signals. A configuration management and control (CMC) module 510 which is coupled to a user interface 512 is further provided to allow a user to define and configure the various output communications messaging formats.

An open connectivity (OPC) client 520 and an open connectivity (OPC) server 522 are further coupled to the database manager. In this arrangement, the OPC client 520 performs OPC requests for data as defined by user setting, whereas the OPC server 522 communicates data to external OPC clients.

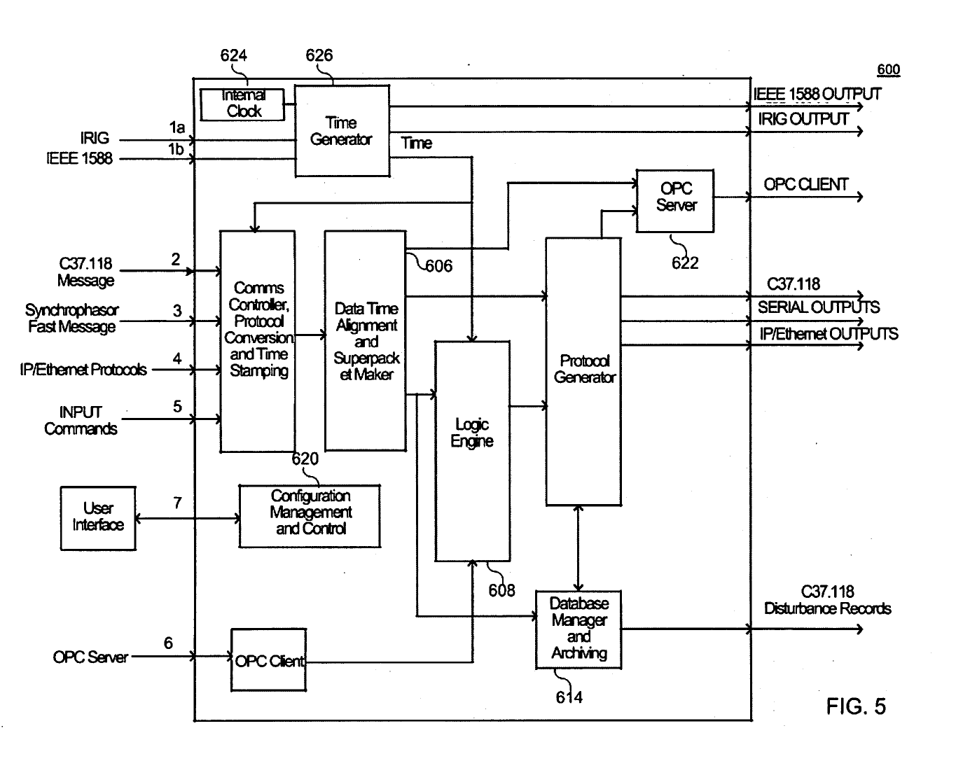

FIG. 5 illustrates another example of the internal architecture of the processor 600. The processor of FIG. 5 is generally similar to that of FIG. 4. However, the data time alignment module 606 of FIG. 5 is further adapted to include a super packet maker 606 which collects and packets all translated data having a common timestamp. Moreover, an internal clock 624 and time generator 626 is coupled to the logic engine 608 in the embodiment of FIG. 5. In this arrangement, the time generator 626 is adapted to receive time information from external time sources such as IRIG and IEEE 1588 and output such time information for internal and external time clients. The time generator 626 is also adapted to receive time information from an internal clock 624. If the external time sources are not available, the internal clock 624 is used. It is also to be noted that OPC client 620 is coupled to the logic engine 608 and the OPC server 622 is coupled to the protocol generator in this embodiment. In this arrangement, the OPC client 620 and the OPC server 622 both circumvent the database manager 614 when performing OPC requests for data as defined by a user setting and communicating data to external OPC clients, respectively.

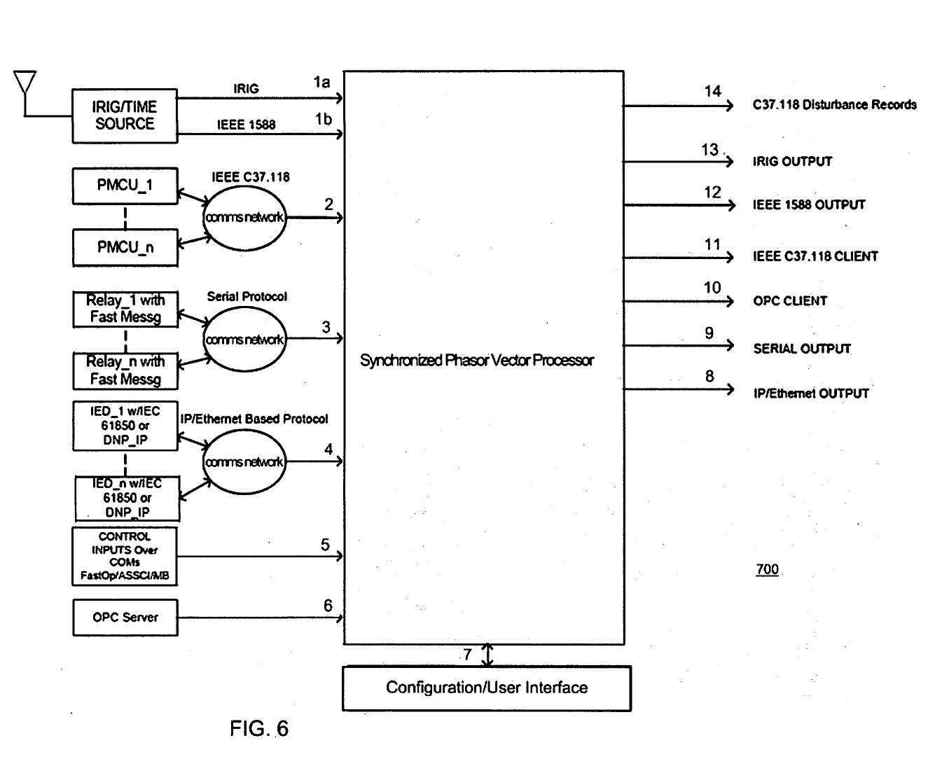

FIG. 6 illustrates the examples various inputs and outputs supported by the processors of FIGS. 4 and 5. Regarding the various inputs, an IRIG-B and IEEE 1588 time input is preferably provided such that an accuracy of better than 1 microsecond is achieved. Other time sources may be provided such as Network Time Protocol (NTP), Simple Network Time Protocol (SNTP), DNP3 timestamps, etc. An IEEE C37.118 input is further provided for receipt of phasor measurement data, synchronized phasor data, time synchronization data, timestamp data, verification measurement compliance data and messaging format data from PMUs and PDCs. A serial input is provided for receipt of what is referred to as fast messages typically about 115 kps or slower using EIA-232 or EIA-485 communication channels. An IP/Ethernet input is provided for receipt of SCADA and protection messages using protocols such as IEEE 37.118, DNP3, Modbus RTU, CANbus, etc. An INPUT Command port is provided for receipt of proprietary control input information such as SEL Fast Message, SEL Remote Bits, SEL Mirrored Bits, etc. A User Configuration input is provided which allows users to set, modify, monitor and/or otherwise configure various elements of the processor 700. An OPC Server Input may further be provided for receipt of OPC requests for data as defined by a user setting.

Regarding the various outputs, the processor 700 provides accurate time information to external devices. An IEEE C37.118 output provides the ability of assembling multiple received C37.118 packets into a single packet and generating a new C37.118 packet with this information. Using the IEEE C37.118 output, the user is also able to configure a new packet with control data available from the logic engine. A Serial Output further provides the ability to generate a command signal upon request of the logic engine. The IP/Ethernet output also provides the ability to generate a command signal upon request of the logic engine using protocols such as IEC 61850-GOOSE, DNP/IP, Modbus/TCP, etc. An OPC Client Output may further provide data to external OPC Client requests.

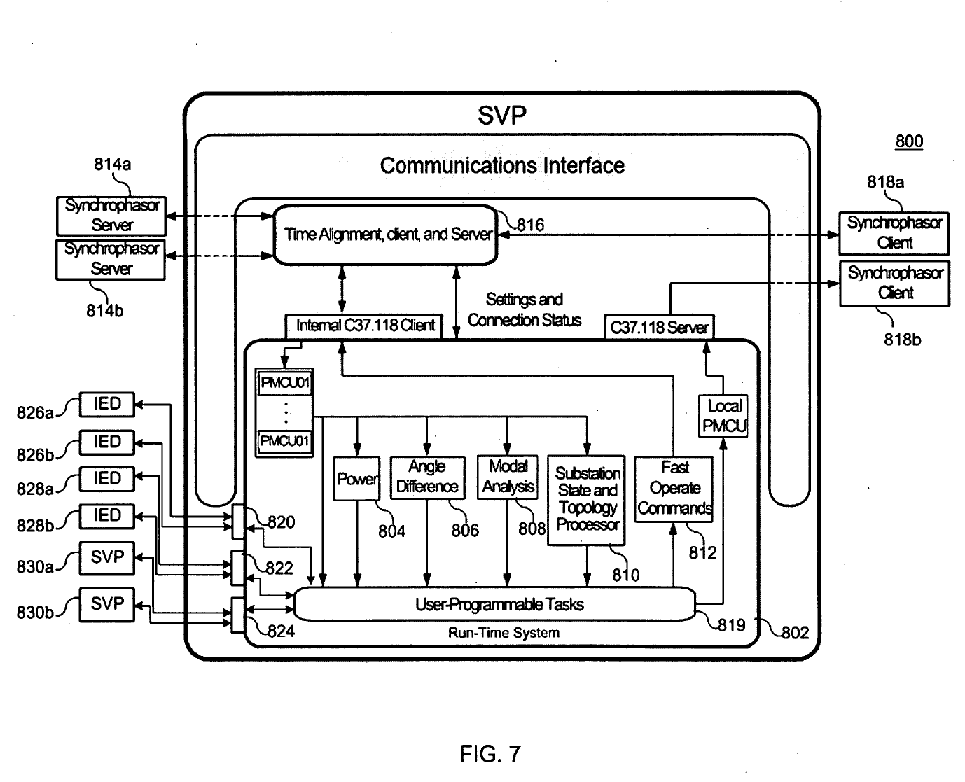

FIG. 7 illustrates yet another embodiment of the internal architecture of the processor. In this embodiment, a processor 800 is provided having a run-time system 802 having a plurality of configurable power system control modules including a power calculation (PWRC) module 804, a phase angle difference monitor (PADM) 806, a modal analysis (MA) module 808, a substation state and topology processor (SSTP) 810, and a fast operate command module 812. Each control module defines a set of scalar, vector and/or other complex calculations for determining control data or an output signal for effecting at least one of the various other power system devices or elements to provide local or wide area protection, control, and monitoring to maintain power system stability of the power system.

Generally, processor 800 includes communications inputs similar to that shown in FIGS. 4-6. More specifically, the processor 800 may generally include a plurality of communications channels for receiving power system data including phasor data, phasor measurements, synchronized phasor measurements, or synchrophasor measurements from a plurality of power system devices or elements associated with an area of the power system (e.g, synchrophasor servers as shown at 814a, b). The power system data may be transferred via a number of communications messaging or protocols format/structures, including but not limited to IEEE C37.118 messages, serial communications, IP/Ethernet protocols (e.g., SCADA, and/or protection messages), input commands and the like.

A time alignment client server (TCS) 816 is provided for correlating and time aligning incoming power system data. The time aligned power system data is provided to the run-time system 802. The run-time system 802 generally includes a power calculation (PWRC) module 804, a phase angle difference monitor (PADM) 806, a modal analysis (MA) module 808, a substation state and topology processor (SSTP) 810, and a fast operate command module 812. Based on the desired power system control, the run-time system uses one or more of the run-time system modules to perform scalar, vector or other complex calculations based on the aligned power system data to provide control data or an output signal for effecting other power system devices or elements to provide local or wide area protection, control, and monitoring to maintain power system stability (e.g., synchrophasor clients as shown at 818a, b). The input and output of the run-time system 802 is preferably transferred using the IEEE C37.118 protocol due to the use of synchrophasors.

Regarding the run-time system 802, the power calculation module 804 generally calculates real and reactive power from voltage and current phasors and, based on such calculation, provides control data or an output signal for effecting other power system devices or elements to provide local or wide area protection , control, and monitoring to maintain power system stability. The phase angle difference monitor 806 generally calculates the angle difference between two phasor angles and, based on such calculation, provides an alarm signal if the difference exceeds a select threshold. The modal analysis module 808 calculates modes of signals available within the real time system and, based on such calculation, provides control data or an output signal for effecting other power system devices or elements to provide local or wide area protection, control, and monitoring to maintain power system stability. The substation state and topology processor 810 identifies measurement errors, calculates current unbalance and symmetrical components, and refines voltage and current measurements. Based on such calculation, the substation and topology processor 810 provides control data or an output signal for effecting other power system devices or elements to provide local or wide area protection, control, and monitoring to maintain power system stability. The fast operate command module 812 is adapted to issue multiple commands to activate remote controls.

These run-time system modules are generally programmable such that a user may customize or define the computations to be calculated thereby via the user-programmable tasks module 819. The run-time system also allows the user to program custom logic independent of the modules mentioned above. Due to the versatility of the various modules of the run-time system, the processor 800 of FIG. 7 may be applied to a number of power system control applications.

Processor 800 further includes communications interfaces 820, 822, 824 for receiving and sending other power system data from a plurality of power system devices or elements associated with an area of the power system (e.g., IEDs shown at 826a, 826b, 828a, 828b, and SVPs shown at 830a, 830b). More specifically, communications interfaces 820, 822, 824 may be adapted to receive and transmit power system data that is not related to phasor data. For example, an IEC 61850-GOOSE interface 820 is provided that may be adapted to send and receive analog and digital GOOSE messages to power system devices or elements associated therewith (e.g., IEDs shown at 826a, 826b). An analog and digital interface 822 is provided (such as Mirrored Bits communications channel) that may be adapted to send and receive analog and digital messages from power system devices or elements associated therewith (e.g., IEDs shown at 828a, 828b). A network parameters interface 824 is provided that may be adapted to send and receive binary data (e.g., analogs, digitals, characters strings, or arrays of the same) to power system devices or elements associated therewith (e.g., SVPs shown at 830a, 830b).

The data received by communication interfaces 820, 822, 824 may be used in the user-programmable tasks module 819 to perform computations independently of any phasor data received via the time alignment client and server 816 and send out the results of these computations via any of the available communications interfaces (e.g., at 820, 822, 824, 812, via the Local PMCU, via OPC, etc.). Alternatively, the data received by communication interfaces 820, 822 824 and/or the aligned power system data from 816 may be used by the run-time system or any one of the run-time system modules to perform scalar, vector or other complex calculations to provide control data or an output signal for effecting other power system devices or elements to provide local or wide area protection, control, and monitoring to maintain power system stability (e.g., synchrophasor clients as shown at 818a, b).

In one such power system control application, the processor of FIG. 7 may be implemented in a power system device within a system integrity protection scheme. In this arrangement, the device is adapted to receive phasor measurements from protective relays. The device generally includes a processor for performing among other things vector and scalar calculations on the phasor measurements along with real values and Boolean values in a time deterministic fashion, to detect power swing oscillations and out-of-step conditions. Using these calculations, the device provides output data and/or signals in order to activate remedial actions to control the protective relays to prevent power system instability.

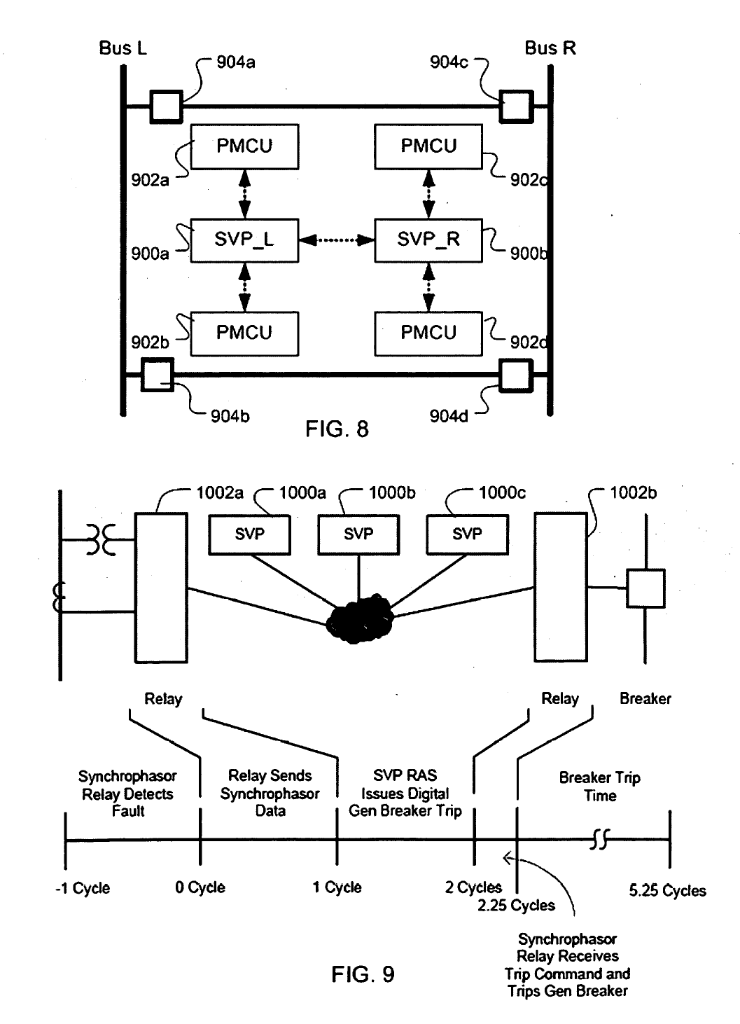

In another power system control application as shown in FIG. 8, the processor of FIGS. 4-7 may be implemented in a plurality of power system devices 900a, 900b to provide a real-time monitoring and warning system. The power system devices 900a, b are generally adapted to receive phasor measurements from various locations in the power system via a plurality of PMCUs 902a, b, c, d. The power system devices 900a, b may further be adapted to time-align these phasor measurements or, alternatively, another associated device (not shown) may be provided to time-align these phasor measurements. The power system devices 900a, b each include a processor similar to any of FIGS. 4-7 for monitoring the quality of the bus voltage measurements in a time deterministic fashion, generally about real-time. The power system devices 900a, b determine whether the line voltages at each bus have magnitude and phase that correspond to the line transfer power and line impedance, thereby signifying that the breakers 904a, b, c, d are closed. For example, at Bus L, power system device 900a collects synchrophasor data from each PMCU 902a, b, c, d and computes an alarm condition if the voltage difference or angle difference is greater than a select threshold. Similarly, at Bus R, power system device 900b collects synchrophasor data from each PMCU 902a, b, c, d and produces an alarm condition if the voltage difference or angle difference is greater than a select threshold.

It is to note that the power system devices 900a, b are adapted to communicate synchrophasor data to each other. Accordingly, this capability allows for a measurement quality check at each of the buses and, therefore, an out-of-tolerance deviation. Using line parameter information and voltage and current synchrophasor data from the other bus, the processor of one of the devices 900a, b may compare the calculated voltage at one of the buses to the measured voltage at that bus. For example, when checking the measurement quality at Bus L, using line parameter information and voltage and current synchrophasor data from Bus R, the processor may calculate the voltage at Bus L using the following equation:

V_{BUS L}=V_{BUS R}+Z·I_{BUS R}

With this result the processor compares the calculated values with the measured values. The processor is adapted to produce an alarm condition if the difference is greater than a select threshold, thereby signaling an out-of-tolerance deviation.

In yet another power system control application as shown in FIG. 9, the processor of FIGS. 4-7 may be implemented in a plurality of power system devices 1000a, b, c in a remedial action scheme (RAS). The power system devices 1000a, b, c are generally adapted to receive phasor measurements from various locations in the power system via a plurality of protective relays (e.g., at 1002a). Because the devices 1000a, b, c are able to process phasor measurements, analog quantities may be directly transmitted from and to the protective relays 1002a, b rather than via post-processed contact outputs as described with respect to the prior art system of FIG. 2. Accordingly, the power system devices 1000a, b, c each include a processor similar to any of FIGS. 4-7 for determining whether there is a loss of load, over-power, etc. In response thereto, the power system devices 1000a, b, c may be adapted to provide control data or a trip signal to protective relay 1002b to perform a remedial action, e.g. effect shedding of an appropriate load. As shown in FIG. 9, the operation time of the arrangement provides for a reduction of about 0.75 cycles of operation time as compared to the prior art system of FIG. 2.

In yet another power system control application, the processor of FIG. 7 may be implemented in a power system device in order to prevent power system inter-area oscillation. Power system disturbances, such as line tripping and drop of generation, cause local and inter-area power system oscillations. Usually, local area oscillation modes range in frequency from about 0.7 to about 2.0 Hz. Inter-area oscillation, which generally refers to a group of generators in one area that swing against a group of generators in another area, normally ranges in frequency from about 0.1 to about 0.8 Hz. The local oscillation involves a few generators within a small portion of a power system and has little impact on an overall power system. Inter-area oscillations constrain the amount of power that can be transferred through some part of interconnected power grids. Without proper remedial actions, inter-area oscillation may result in power system separations or major blackouts.

The traditional approach to preventing inter-area oscillation involves modal analysis of power system dynamic simulation results at the planning stage. Nevertheless, in this embodiment provided is a device which is adapted to receive phasor measurements from protective relays. The device generally includes a processor including a Modal Analysis module 808 as shown in FIG. 7 for performing modal analysis calculations on the phasor measurements along with real values and Boolean values in a time deterministic fashion, to detect unstable inter-area oscillations. In one embodiment, the Modal Analysis module 808 uses a Modified Prony Analysis which uses the linear combination of multiple exponential oscillation modes to approximate an original signal that a device samples at fixed time intervals. Using these calculations, the device provides output data and/or signals in order to activate remedial actions to control the protective relays to mitigate inter-area oscillations in real-time.

In yet another power system control application, the processor of FIG. 7 may be implemented in a power system device in order to provide distributed busbar differential protection. Generally, in this arrangement, a processor including the substation state and topology module 810 of FIG. 7 acquires current phasor measurements at the busbar terminals in a local area and provides trip commands to the terminal breakers to achieve distributed busbar differential protection. More specifically, the substation state and topology module 810 processes busbar topology information to determine the appropriate protection zones; detects busbar faults from the acquired current phasor measurements and protection zone information; and provides trip commands to appropriate power system devices to clear any detected busbar faults. The substation state and topology processor 810 determines the appropriate protection zones by generating lists of branches within each protection zone using busbar topology information, the status of breakers and disconnects, the current transformer polarities and the terminal current measurements.

While this invention has been described with reference to certain illustrative aspects, it will be understood that this description shall not be construed in a limiting sense. Rather, various changes and modifications can be made to the illustrative embodiments without departing from the true spirit, central characteristics and scope of the invention, including those combinations of features that are individually disclosed or claimed herein. Furthermore, it will be appreciated that any such changes and modifications will be recognized by those skilled in the art as an equivalent to one or more elements of the following claims, and shall be covered by such claims to the fullest extent permitted by law.

1. A device for monitoring and controlling various power system devices or elements, the device comprising:
a communications channel for receiving phasor data associated with a location on the power system; and
a processor including a logic engine to perform scalar, vector and/or other complex calculations based on the phasor data to provide control data or an output signal for effecting the various other power system devices or elements to provide local or wide area protection and/or monitoring of the power system.

2. The device of claim 1 wherein the received phasor data includes phasor measurement data, synchronized phasor measurement data or synchrophasor data.

3. The device of claim 1 wherein the communications channel is further adapted to receive other power system data in addition to the phasor data, and the logic engine is adapted to perform scalar, vector and/or other complex calculations based on the other power system data to provide control data or an output signal for effecting the various other power system devices or elements to provide local or wide area protection and/or monitoring of the power system.

4. The device of claim 1 wherein the phasor data includes time information.

5. The device of claim 1 wherein the phasor data is timestamped, and the processor is configured to form the time-aligned phasor data according to the timestamp.

6. The device of claim 5, wherein the timestamp is derived from a common time.

7. The device of claim 6, wherein the common time is absolute time.

8. The device of claim 4 further comprising a data time-alignment module for correlating the phasor data.

9. The device of claim 5 further comprising a clock, wherein said phasor data is timestamped based on said clock.

10. The device of claim 1 wherein the phasor data is received in various messaging formats, said device further comprising a protocol conversion module for translating the various received messages into a common data format.

11. The device of claim 1 further comprising a protocol generator coupled to the logic engine for converting the control data or output signal to an appropriate messaging format or protocol understandable by other power system devices or elements.

12. The device of claim 11, wherein the messaging format comprises a user configurable message using available quantities within the logic engine.

13. The device of claim 1 wherein said processor is configurable to define various scalar, vector and/or other complex calculations to be processed thereby.

14. The device of claim 1 further comprising an open connectivity (OPC) client adapted to perform OPC requests for phasor data.

15. The device of claim 1 further comprising an open connectivity (OPC) server adapted to communicate control data to external OPC clients.

16. The device of claim 1 further comprising a database coupled to the logic engine for storage of control data, said control data being retrievable by the logic engine for use in its calculations.

17. The device of claim 1 further comprising a run-time system having a plurality of configurable power system control modules, each control module defining a set of scalar, vector and/or other complex calculations for determining control data or an output signal for effecting at least one of the various other power system devices or elements to provide local or wide area protection and/or monitoring of the power system.

18. The device of claim 17 wherein one of the power system control modules is a power calculation module defining the calculation of real and reactive power from the phasor data, and wherein the power calculation module is adapted to provide control data or an output signal for effecting other power system devices or elements to provide local or wide area protection and monitoring based on said calculation.

19. The device of claim 17 wherein one of the power system control modules is a phase angle difference monitor defining the calculation of the angle difference between phasor angles of the phasor data, and wherein the phase angle difference module is adapted to provide an alarm signal if the angle difference exceeds a select threshold.

20. The device of claim 17 wherein one of the power system control modules is a modal analysis module defining the determination of modes of signals available within the power system, and wherein the modal analysis module is adapted to provide control data or an output signal for effecting other power system devices or elements to provide local or wide area protection and monitoring based on such determination.

21. The device of claim 17 wherein one of the power system control modules is a topology processor defining the determination of appropriate protection zones and the detection of busbar faults from the phasor data, and wherein the Page 21 of 26 topology processor is adapted to provide a trip command to one of the other power system devices or elements to clear any detected busbar faults.

22. The device of claim 17 wherein one of the power system control modules is a fast operate command module adapted to control remote power system devices or elements.

23. The device of claim 1 wherein one of the effected power system devices is a protective relay.

24. The device of claim 1 further adapted to receive time information from an external time.

25. The device of claim 23 further adapted to provide a time reference for any one of the received phasor data, the processor, or the control data based on the received time information.

26. The device of claim 23, further adapted to provide a time reference for any received data received without an associated time reference.

27. A system for monitoring and protecting an area of a power system, the system comprising:
a plurality of phasor measurement units for acquiring phasor data from the area of the power system;
a control device having a communications channel for receiving the phasor data and a processor including a logic engine for performing scalar, vector and/or other complex calculations based on the phasor data to provide control data or an output signal; and
a plurality of other power system devices or elements adapted to receive the control data or output signals and in response thereto provide protection and/or monitoring to the area of the power system.

28. The system of claim 27 wherein the phasor data includes phasor measurement data, synchronized phasor measurement data or synchrophasor data.

29. The system of claim 27 wherein the communications channel of the control device is further adapted to receive other power system data in addition to the phasor data, and the logic engine is adapted to perform scalar, vector and/or other complex calculations based on the other power system data to provide control data or an output signal.

30. The system of claim 27 wherein the phasor data includes time information.

31. The system of claim 27 wherein the phasor data is timestamped, and the control device is configured to form the time-aligned phasor data according to the timestamp.

32. The system of claim 31, wherein the timestamp is derived from a common time.

33. The system of claim 32, wherein the common time is absolute time.

34. The system of claim 0 wherein the control device further comprises a data time-alignment module for correlating the phasor data.

35. The system of claim 31 further comprising a clock, wherein said phasor data is timestamped based on said clock.

36. The system of claim 27 wherein the phasor measurement units transmit the phasor data in various messaging formats, and wherein said control device further comprises a protocol conversion module for translating the various received messages into a common data format.

37. The system of claim 27 wherein the control device further comprises a protocol generator coupled to the logic engine for converting the control data or output signal to an appropriate messaging format or protocol understandable by other power system devices or elements.

38. The system of claim 37, wherein the messaging format comprises a user configurable message using available quantities within the logic engine.

39. The system of claim 27 wherein the processor of the control device is configurable to define various scalar, vector and/or other complex calculations to be processed thereby.

40. The system of claim 27 wherein the control device further comprises a run-time system having a plurality of configurable power system control modules, each control module defining a set of scalar, vector and/or other complex calculations for determining control data or an output signal for effecting at least one of the various other power system devices or elements to provide local or wide area protection and/or monitoring of the power system.

41. The system of claim 40 wherein one of the power system control modules is a power calculation module defining the calculation of real and reactive power from the phasor data, and wherein the power calculation module is adapted to provide control data or an output signal for effecting other power system devices or elements to provide local or wide area protection and monitoring based on said calculation.

42. The device of claim 40 wherein one of the power system control modules is a phase angle difference monitor defining the calculation of the angle difference between phasor angles of the phasor data, and wherein the phase angle difference module is adapted to provide an alarm signal if the angle difference exceeds a select threshold.

43. The device of claim 40 wherein one of the power system control modules is a modal analysis module defining the determination of modes of signals available within the power system, and wherein the modal analysis module is adapted to provide control data or an output signal for effecting other power system devices or elements to provide local or wide area protection and monitoring based on such determination.

44. The device of claim 40 wherein one of the power system control modules is a topology processor defining the determination of appropriate protection zones and the detection of busbar faults from the phasor data, and wherein the topology processor is adapted to provide a trip command to one of the other power system devices or elements to clear any detected busbar faults.

45. The device of claim 40 wherein one of the power system control modules is a fast operate command module adapted to control remote power system devices or elements.
